(19) United States
(12) Patent Application Publication
(10) Pub. No.: US 2026/0118419 A1
(43) Pub. Date: Apr. 30, 2026

(54) Machine Learning for Syncing Multiple FPGA Ports in a Quantum System

(71) Applicant: Quantum Machines, Tel Aviv (IL)

(72) Inventors: Avishai ZIV, Tel Aviv (IL); Ori WEBER, Tel Aviv (IL); Nissim OFEK, Tel Aviv (IL)

(21) Appl. No.: 18/907,706

(22) Filed: Oct. 7, 2024

Related U.S. Application Data
(63) Continuation of application No. 17/582,207, filed on Jan. 24, 2022, now Pat. No. 12,111,352.

(51) Int. Cl. G01R 31/317; G06N 10/20; G06N 10/60

(52) U.S. Cl. CPC G01R 31/31703; G01R 31/31712; G06N 10/20; G06N 10/60

(57) ABSTRACT

In a quantum computer, quantum algorithms are performed by a qubit interacting with multiple quantum control pulses. The quantum control pulses are electromagnetic RF signals that are generated digitally at baseband and sent, via asynchronous ports, to DACs that feed an RF upconversion circuit. For synchronization, each asynchronous port is coupled to a multi-tap delay line. The setting of the multi-tap delay line is determined by a function of the port's setup-and-hold time. This function is trained, via machine learning, to be applicable across a variety of ports.

### BACKGROUND

Limitations and disadvantages of the conventional use of multiple FPGA ports will become apparent to one of skill in the art, through comparison of such approaches with some aspects of the present method and system set forth in the remainder of this disclosure with reference to the drawings.

### BRIEF SUMMARY

Methods and systems are provided for syncing multiple FPGA ports in a quantum system, substantially as illustrated by and/or described in connection with at least one of the figures, as set forth more completely in the claims.

### BRIEF DESCRIPTION OF THE DRAWINGS

FIG. 1 illustrates an example quantum system comprising multiple FPGA ports that are synced in accordance with various example implementations of this disclosure.

FIG. 2 illustrates an example system for training a quantum system to sync multiple FPGA ports in accordance with various example implementations of this disclosure.

FIG. 3 illustrates a flowchart of an example method for syncing multiple FPGA ports in accordance with various example implementations of this disclosure.

FIG. 4 illustrates an example graph of phase values measured over a range of delays in accordance with various example implementations of this disclosure.

FIG. 5 illustrates an example tap/delay estimate function as a linear fit to the ideal phase values for different ports having different setup-and-hold times in accordance with various example implementations of this disclosure.

### DETAILED DESCRIPTION

Classical computers operate by storing information in the form of binary digits (“bits”) and processing those bits via binary logic gates. At any given time, each bit takes on only one of two discrete values: 0 (or “off”) and 1 (or “on”). The logical operations performed by the binary logic gates are defined by Boolean algebra and circuit behavior is governed by classical physics. In a modern classical system, the circuits for storing the bits and realizing the logical operations are usually made from electrical wires that can carry two different voltages, representing the 0 and 1 of the bit, and transistor-based logic gates that perform the Boolean logic operations.

Logical operations in classical computers are performed on fixed states. For example, at time 0 a bit is in a first state, at time 1 a logic operation is applied to the bit, and at time 2 the bit is in a second state as determined by the state at time 0 and the logic operation. The state of a bit is typically stored as a voltage (e.g., 1 Vdc for a “1” or 0 Vac for a “0”). The logic operation typically comprises of one or more transistors.

Obviously, a classical computer with a single bit and single logic gate is of limited use, which is why modern classical computers with even modest computation power contain billions of bits and transistors. That is to say, classical computers that can solve increasingly complex problems inevitably require increasingly large numbers of bits and transistors and/or increasingly long amounts of time for carrying out the algorithms. There are, however, some problems which would require an infeasibly large number of transistors and/or infeasibly long amount of time to arrive at a solution. Such problems are referred to as intractable.

Quantum computers operate by storing information in the form of quantum bits (“qubits”) and processing those qubits via quantum gates. Unlike a bit which can only be in one state (either 0 or 1) at any given time, a qubit can be in a superposition of the two states at the same time. More precisely, a quantum bit is a system whose state lives in a two dimensional Hilbert space and is therefore described as a linear combination α|0 [symbol] +β|1 [symbol] , where |0 [symbol] and |1 [symbol] are two basis states, and α and β are complex numbers, usually called probability amplitudes, which satisfy |α|²+|β|²=1. Using this notation, when the qubit is measured, it will be 0 with probability |α|² and will be 1 with probability |β|². The basis states |0 [symbol] and |1 [symbol] can also be represented by two-dimensional basis vectors

$$[ \begin{matrix}1 \\ 0\end{matrix} ] and [ \begin{matrix}0 \\ 1\end{matrix} ] ,$$

respectively. The qubit state may represented by

$$[ \begin{matrix}α \\ β\end{matrix} ] .$$

The operations performed by the quantum gates are defined by linear algebra over Hilbert space and circuit behavior is governed by quantum physics. This extra richness in the mathematical behavior of qubits and the operations on them, enables quantum computers to solve some problems much faster than classical computers. In fact, some problems that are intractable for classical computers may become trivial for quantum computers.

Unlike a classical bit, a qubit cannot be stored as a single voltage value on a wire. Instead, a qubit is physically realized using a two-level quantum mechanical system. For example, at time 0 a qubit is described as

$$[ \begin{matrix}{α}_{1} \\ {β}_{1}\end{matrix} ] ,$$

at time 1 a logic operation is applied to the qubit, and at time 2 the qubit is described as

$$[ \begin{matrix}{α}_{2} \\ {β}_{2}\end{matrix} ] .$$

Many physical implementations of qubits have been proposed and developed over the years. Some examples of qubits implementations include superconducting circuits, spin qubits, and trapped ions.

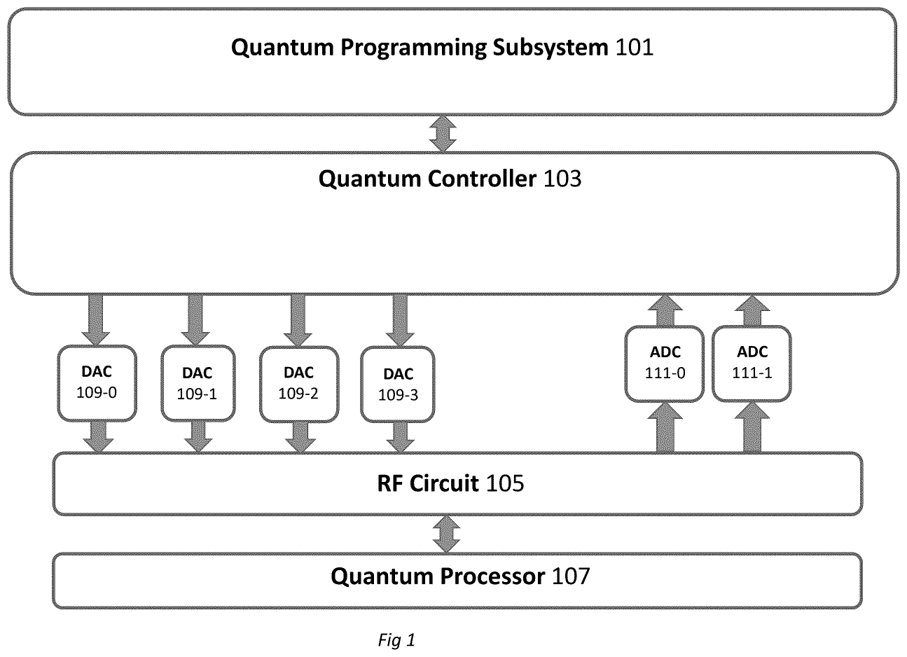

FIG. 1 illustrates an example quantum system comprising multiple FPGA ports that are synced in accordance with various example implementations of this disclosure. The quantum system comprise a quantum programming subsystem (QPS) 101, a quantum controller (QC) 103, and a quantum processor 107.

The QPS 101 is capable of generating a quantum algorithm description which configures the QC 103 and includes instructions the QC 103 can execute to carry out the quantum algorithm (i.e., generate the necessary outbound quantum control pulse(s)) with little or no human intervention during runtime. In an example implementation, the QPS 101 is a personal computer comprising a processor, memory, and other associated circuitry (e.g., an x86 or x64 chipset). The QPS 101 compiles the high-level quantum algorithm description to a machine code version of the quantum algorithm description (i.e., series of binary vectors that represent instructions that the QC 103 can interpret and execute directly).

The QPS 101 may be coupled to the QC 103 via an interconnect which may, for example, utilize a universal serial bus (USB), a peripheral component interconnect (PCIe) bus, wired or wireless Ethernet, or any other suitable communication protocol.

The QC 103 comprises circuitry operable to load the machine code quantum algorithm description from the QPS 101 via the interconnect. Execution of the machine code by the QC 103 causes the QC 103 to generate the necessary outbound quantum control pulse(s) that correspond to the desired operations to be performed on the quantum processor 107 (e.g., sent to qubit(s) for manipulating a state of the qubit(s) or to readout resonator(s) for reading the state of the qubit(s), etc.). The machine code may also cause the QC 103 to perform an analysis on an input signal. The analysis result may be used to determine the state of the qubit or the quantum register (quantum measurement). Depending on the quantum algorithm to be performed, outbound pulse(s) for carrying out the algorithm may be predetermined at design time and/or may need to be determined during runtime. The runtime determination of the pulses may comprise performance of classical calculations and processing in the QC 103 during runtime of the algorithm (e.g., runtime analysis of inbound pulses received from the quantum processor).

A QC 103 generates the precise series of external signals, usually pulses of electromagnetic waves and pulses of base band voltage, to perform the desired logic operations (and thus carry out the desired quantum algorithm).

During runtime and/or upon completion of a quantum algorithm performed by the QC 103, the QC 103 may output data/results to the QPS 101. In an example implementation these results may be used to generate a new quantum algorithm description for a subsequent run of the quantum algorithm and/or update the quantum algorithm description during runtime. Additionally, the QC 103 may output the raw or processed inbound pulses received from the quantum processor 107, representing qubits state estimation, or metadata representing the quantum program control flow and branching information, as well as internal variables computations during the program execution.

A QC 103 comprises a plurality of pulse processors, which may be implemented in a field programmable gate array (FPGA), an application specific integrated circuit or the like. A pulse processor is operable to control analog outbound pulses that drive a quantum element (e.g., one or more qubits and/or resonators) or allow interaction between quantum elements and digital outbound pulses that can control auxiliary equipment required for the program execution (e.g., gating the analog outbound pulses or controlling external devices like photon detectors).

Quantum algorithms are performed in the quantum processor 107 when one or more qubits interact with quantum control pulses. These quantum control pulses are electromagnetic RF signals or pulses that are generated digitally at baseband in the QC 103, converted to an analog waveform via a plurality of DACs 109-0, 109-1, 109-2 and 109-3, and upconverted by an RF circuit 105. The desired signals may generated according to a known set of instructions, involving various operations such as arithmetical or logical calculations, communication with various components and classical control flow operations (jump, branch, etc.). An application layer (APP) in the QC 103 controls a physical layer (PHY) to digitally generate (and further modify) samples of this analog waveform. Inbound pulses are also received by the QC 103, from the quantum processor 107, via the RF circuit 105 and a plurality of ADCs 111-0 and 111-1.

A qubit may have a life in the range of hundreds of microseconds, causing a very low program execution runtime. Also, in data centers where a quantum computer is acting as a co-accelerator for specific computations there may be thousands of programs that are queuing to use the designated quantum processor 107.

As the process, voltage and temperature (PVT) changes, a periodic recalibration may be in order. Therefore, a fast, robust and independent approach to recalibration may facilitate a much better usage of the quantum computer while minimizing dead time between programs.

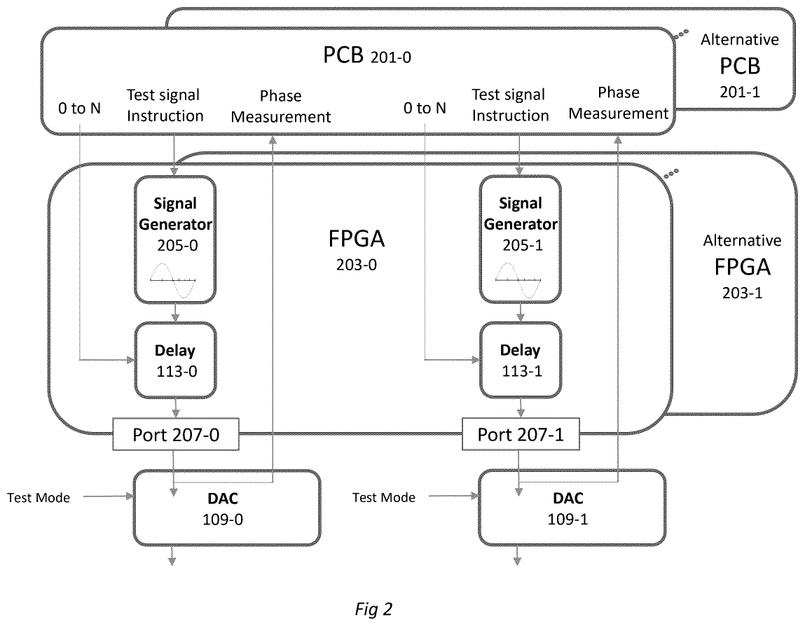

FIG. 2 illustrates an example system for training a quantum system to sync multiple FPGA ports in accordance with various example implementations of this disclosure.

The quantum controller 103 in FIG. 1 may comprise a PCB 201-0 and an FPGA 203-0. FPGA 203-0 may have numerous ports 207-0 and 207-1 which need to be synced to one another. Furthermore, the PCB 201-0 and FPGA 203-0 may have design variations 201-1 and 203-1, respectively, such that transmission via ports 207-0 and 207-1 of FPGA 203-0 may not be aligned with transmission via ports 207-0 and 207-1 of FPGA 203-1. Synchronization is required for the outputs, driven from FPGA 203-0 or 203-1, to arrive at all DACs 109-0 and 109-1 simultaneously and independently, without skews regardless of the design variations between similar system components. Any delay or misalignment of one of the signals that are being output from the FPGA 203-0 or 203-1 can drastically impair the reliability of the quantum computer.

The hardware path from the FPGA 203-0 to the ports 207-0 and 207-1 may change because of variants in FPGAs 203-1 (e.g., same PCB 201-0 revision, but an FPGA 203-1 from a different batch). The various characteristics of the FPGA 203-1 can influence the time that it takes the signal to arrive at a DAC 109-0 and 109-1 and ruin the sync that was calibrated for a different PCB 201. For the purpose of training this machine learning model, several FPGA designs 203-0 and 203-1, each with a different layout, as well as several quantum control units with different PCBs 201-0 and 201-1 are used for training.

Syncing ports 207-0 and 207-1 in the FPGA 203-0 and/or 203-1 incorporates delay lines 113-0 and 113-1 for each port 207-0 and 207-1. This allows the signal driven from the FPGA 203-0 and/or 203-1 to be programmatically and digitally “shifted,” in constant and discrete steps such that all signals are aligned at their destinations as required by the quantum control application.

A machine learning approach is disclosed for syncing all quantum FPGA ports 207-0 and 207-1, without having to save, load and maintain previously acquired data per quantum control unit (i.e., without using external storage). The machine learning approach also eliminates the need for long and repetitive calibrations on the quantum control platform, along with eliminating the need to calibrate using external input/output devices.

To train the machine learning model, information from different PCBs 201-0 and/or 201-1 and different FPGA logic designs 203-0 and/or 203-1 is collected per port 207-0 and 207-1. Training is required only once.

Test signals may be generated by generator 205-0 and 205-1. The test signals may be sinusoidal signals or any other signals with a deterministic phase. For each PCB 201-0 or 201-1, per FPGA design 203-0 or 203-1, the span of possible delays (0 to N) are programmed in the delay lines 113-0 and 113-1. The phase of the test signal at each DAC 109-0 and 109-1 is measured. This provides the information of which tap/delay is required for each port 207-0 and 207-1. Test signals at the DACs 109-0 and 109-1 are synchronized when they have the same phase. A formula for determining the tap/delay, as a function of a port's setup and hold time, may be derived from the measured phase values using linear regression. Alternatively, a non-linear equation for determining the tap/delay may be derived to account for delay lines that are non-linear.

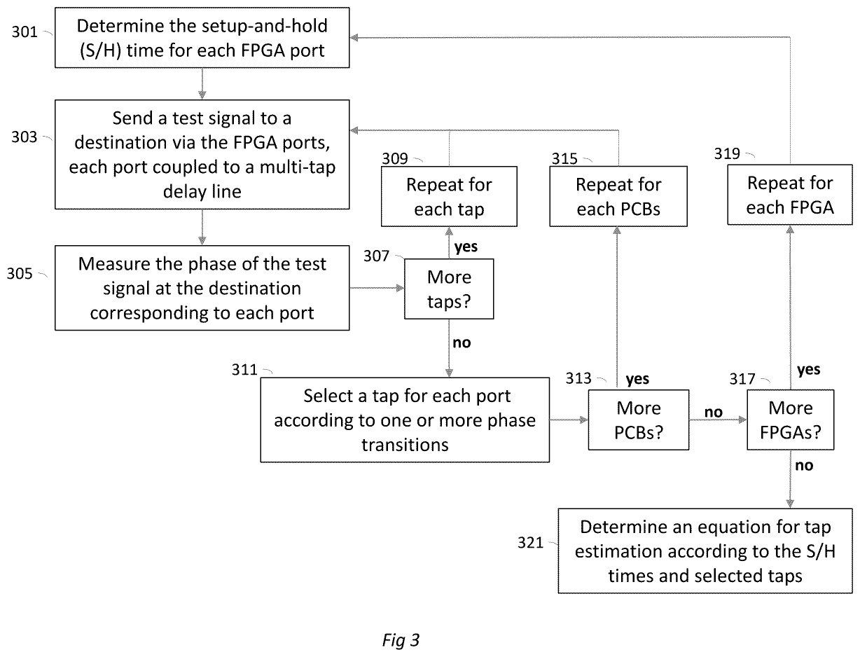

FIG. 3 illustrates a flowchart of an example method for syncing multiple FPGA ports in accordance with various example implementations of this disclosure.

Each of the FPGA logic designs is characterized by setup-and-hold (S/H) times which also serves as part of the input to the training phase. At 301, the S/H times are determined for each port of an FPGA. The FPGA ports may be asynchronous.

A test signal is generated. At 303, the test signal is sent, via each of the FPGA ports, to a destination. The destination may be a DAC. Each FPGA port is coupled to a multi-tap delay line. Each of the plurality of multi-tap delay lines is initiated by setting a tap (i.e., a selectable delay).

At 305, a phase of the test signal, as received at the destination from every port, is measured. For example, if each of 8 ports sends a sinusoidal test signal to each of 8 DACs, the test signals, received at each DAC, are processed to determine the phase values.

At 307, it is determined whether all taps have been used. If more taps are available, at 309, the next tap is chosen, the test signal is resent at 303 and the phase values of the test signal, as received at the destination from every port, is measured at 305.

Once each tap/delay is chosen and the data collection stage is done, an application is operable, at 311, to select an ideal tap/delay, from the plurality of phase values, for each of the plurality of ports. The ideal tap/delay for every ports will correspond to the same phase.

At 313, it is determined whether more PCBs are available for training. If more PCBs are available, at 315, a new PCB is used, the tap/delay is reinitialized for each delay line, the test signal is resent at 303 and the phase values of the test signal, as received at the destination from every port, is measured at 305.

At 317, it is determined whether more FPGAs are available for training. If more FPGAs are available, at 319, a new FPGA is used, the tap/delay is reinitialized for each delay line, the test signal is resent at 303 and the phase values of the test signal, as received at the destination from every port, is measured at 305.

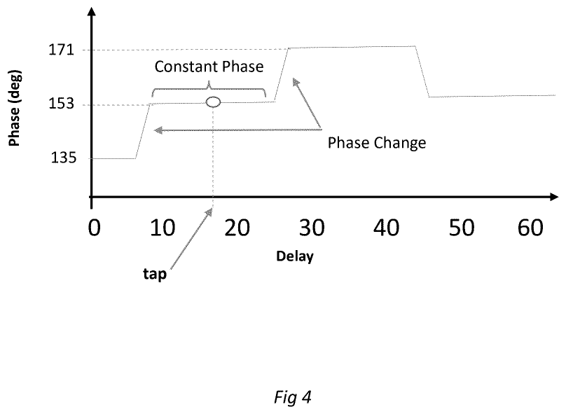

FIG. 4 illustrates an example graph of phase values measured over a range of delays in accordance with various example implementations of this disclosure.

The horizontal axis is the delay-line value (i.e., the amount of time units the test signal is delayed). The vertical axis is the measured phase. A graph like this can be generated for each port.

As illustrated, the tap setting in each delay line may be from 0 to 63. This range is an example, as any range may be used. Ideally, each tap would correspond to an exact delay. For example, a range of 0 to 4 nsec with a 62.5 psec resolution. However, an exact delay is sometimes not possible, and a linear relationship between time and taps is not a requirement for this method.

As illustrated, the test signal is a sinusoidal wave, although any test signal with a deterministic phase may be used. The ideal tap/delay is selected as 18, as 18 corresponds to center of a period of constant phase. The selected ideal tap, for a particular port of the plurality of asynchronous ports, may, therefore, be determined according to a point halfway between 2 phase changes. In other embodiments, the test signal may comprises a pulse. For a test signal pulse, the selected ideal tap, may be based on a phase transition (i.e., on to off or vice versa).

Turning back now to FIG. 3, at 321, a tap estimate function is generated according to the selected/ideal taps, as well as a setup-and-hold time, for each of the plurality of ports.

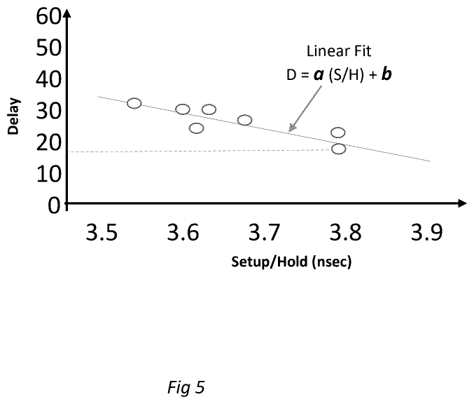

FIG. 5 illustrates an example tap/delay estimate function as a linear fit to the ideal phase values (as discussed regarding FIG. 4) for different ports having different setup-and-hold times in accordance with various example implementations of this disclosure.

Using linear regression on the training data, coefficients a and b may be determined such that the following function fits the collected data:

$$Delay = a ( S / H ) + b$$

where S/H is the setup-and-hold time of a port (this can change per FPGA logic design), and Delay is the required delay for the port, such that all ports in a specific PCB are synchronized.

This machine learning approach may determine an optimal delay for different logic designs, different PVT, different batches of FPGA chips. This optimal delay may achieved without repeated calibration using external wiring and persistent storage.

The present method and/or system may be realized in hardware, software, or a combination of hardware and software. The present methods and/or systems may be realized in a centralized fashion in at least one computing system, or in a distributed fashion where different elements are spread across several interconnected computing systems. Any kind of computing system or other apparatus adapted for carrying out the methods described herein is suited. A typical implementation may comprise one or more application specific integrated circuit (ASIC), one or more field programmable gate array (FPGA), and/or one or more processor (e.g., x86, x64, ARM, PIC, and/or any other suitable processor architecture) and associated supporting circuitry (e.g., storage, DRAM, FLASH, bus interface circuits, etc.). Each discrete ASIC, FPGA, Processor, or other circuit may be referred to as “chip,” and multiple such circuits may be referred to as a “chipset.” Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to perform processes as described in this disclosure. Another implementation may comprise a non-transitory machine-readable (e.g., computer readable) medium (e.g., FLASH drive, optical disk, magnetic storage disk, or the like) having stored thereon one or more lines of code that, when executed by a machine, cause the machine to be configured (e.g., to load software and/or firmware into its circuits) to operate as a system described in this disclosure.

As used herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As used herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As used herein, the term “exemplary” means serving as a non-limiting example, instance, or illustration. As used herein, the terms “e.g.,” and “for example” set off lists of one or more non-limiting examples, instances, or illustrations. As used herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.). As used herein, the term “based on” means “based at least in part on.” For example, “x based on y” means that “x” is based at least in part on “y” (and may also be based on z, for example).

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1-20. (canceled)

21. A system comprising:
a plurality of multi-tap delay lines configured to output a plurality of delayed signals, via a plurality of asynchronous ports, according to a tap estimate function; and
an application configured to generate the tap estimate function according to a measurement of phase values corresponding to each tap of each multi-tap delay line.

22. The system of claim 21, wherein the tap estimate function is generated according to a setup-and-hold time for each of the plurality of asynchronous ports.

23. The system of claim 21, wherein a field programmable gate array (FPGA) comprises the plurality of asynchronous ports.

24. The system of claim 21, wherein an FPGA comprises the plurality of multi-tap delay lines.

25. The system of claim 21, wherein the tap estimate function is generated according to phase measurements from a plurality of FPGAs.

26. The system of claim 21, wherein the plurality of delayed signals are output to one or more digital-to-analog converters (DACs).

27. The system of claim 21, wherein the plurality of delayed signals comprises a sinusoidal wave.

28. The system of claim 21, wherein the plurality of delayed signals comprises a pulse.

29. The system of claim 21, wherein a delayed signal of the plurality of delayed signals corresponds to a period of constant phase.

30. The system of claim 21, wherein a delayed signal of the plurality of delayed signals is determined according to one or more phase changes.

31. The system of claim 21, wherein the measurement of phase values occurs with a test signal is input to each of the plurality of multi-tap delay lines.

32. The system of claim 21, wherein the measurement of phase values occurs with at a destination of the plurality of delayed signals.

33. The system of claim 21, wherein the measurement of phase values comprises selecting a tap of each multi-tap delay line.

34. The system of claim 21, wherein the tap estimate function is generated according to a linear regression.

35. The system of claim 21, wherein the tap estimate function is generated according to a non-linear equation.

36. A method comprising:
generating a tap estimate function according to a measurement of phase values corresponding to each tap of each of a plurality of multi-tap delay lines; and
outputting a plurality of delayed signals, via a plurality of asynchronous ports operably coupled to the plurality of multi-tap delay lines, according to a tap estimate function.

37. The method of claim 36, wherein the tap estimate function is generated according to a setup-and-hold time for each of the plurality of asynchronous ports.

38. The method of claim 36, wherein the measurement of phase values comprises selecting a tap of each multi-tap delay line.

39. The method of claim 36, wherein the tap estimate function is generated according to a linear regression.

40. The method of claim 36, wherein the tap estimate function is generated according to a non-linear equation.
